(19) United States
(12) Patent Application Publication
(10) Pub. No.: US 2006/0283546 A1
(43) Pub. Date: Dec. 21, 2006

(54) Method for encapsulating electronic devices and a sealing assembly for the electronic devices

(76) Inventors: James Daniel Tremel, Santa Barbara, CA (US); Matthew Dewey Hubert, Goleta, CA (US)

Correspondence Address: E I DU PONT DE NEMOURS AND COMPANY;LEGAL PATENT RECORDS CENTER, BARLEY MILL PLAZA 25/1128, 4417 LANCASTER PIKE, WILMINGTON, DE, 19805, US

(21) Appl. No.: 11/447,210

(22) Filed: Jun. 5, 2006

Related U.S. Application Data
(63) Continuation-in-part of application No. 10/984,451, filed on Nov. 9, 2004.
(60) Provisional application No. 60/519,319, filed on Nov. 12, 2003.

(51) Int. Cl. B05D 5/12; C23C 16/00; B32B 37/12

(52) U.S. Cl. 156/291; 427/248.1; 427/58; 156/330

(57) ABSTRACT

A method for sealing an electronic device includes providing an electronic device on a substrate, providing a lid, activating a getter material in an environment substantially free of contaminants, applying a sealing material to at least a portion of the lid, and attaching the substrate and the lid in an inert environment. The time elapsed between activating the getter material and attaching the substrate and the lid is less than 20 minutes. A sealing assembly for an electronic device includes an activation tool for activating a getter material, a dispensing tool for dispensing a sealing material, and an encapsulation tool for sealing the electronic device. The sealing assembly is in an environment substantially free of contaminants.

### CROSS REFERENCE TO RELATED APPLICATIONS

This is a Continuation-In-Part of application Ser. No. 10/984,451, filed on Nov. 9, 2004, which claims priority to Provisional Application Ser. No. 60/519,139, filed on Nov. 12, 2003, both of which are incorporated herein by reference in their entirety.

### BACKGROUND INFORMATION

1. Field of the Disclosure

This disclosure relates in general to a method for encapsulating electronic devices and a sealing assembly for the electronic devices.

2. Description of the Related Art

Organic electronic devices are sensitive to, and have decreased performance, when critical components are exposed to undesirable contaminants, including moisture and other contaminant gases, such as oxygen, hydrogen, and organic gases. For example, the relatively low work function metals, such as barium or calcium, are often used as the cathode material in electronic organic devices for device performance reasons. Unfortunately, low work function metals such as calcium, barium and strontium typically react with oxygen and form water vapor. These reactions destroy their required low work function property.

Another example of the destructive nature of contaminants in organic electronic devices occurs in organic light-emitting diode displays (“OLEDs”). OLEDs are fabricated using thin films of luminescent organic molecules as the active layers, which layers must be protected from degradation by moisture and other contaminant gases.

Current techniques for protecting organic electronic devices from such degradation include applying an environmental barrier coat to the outside of the organic electronic device, putting an absorbent or adsorbent getter material on the edges of the device where contaminants enter into the interior of the organic electronic device or within an enclosure containing the organic electronic device to enclose the materials most sensitive to contaminant gases with the getter material.

Manufacture of organic electronic devices presents certain process limitations to the use of getters. Absorbent getters are inherently moisture sensitive and the absorption reaction is not reversible, requiring manufacture in a low moisture environment. Adsorbent getters, on the other hand, commonly contain zeolites and other molecular sieve materials that must be heated for activation at temperatures up to about 650° C. and sealed within a device in a controlled atmosphere. However the active organic materials in organic electronic devices will not withstand temperatures much above about 300° C., requiring that the remaining materials in the device, to be useful, will need to be applied and heat treated in a manner that does not interfere with the overall manufacturing requirements of the device.

In addition, traditional getter materials are hard to form into the variety of shapes and sizes needed to accommodate the wide variety of designs for organic electronic devices and require expensive tooling equipment for manufacture.

One strategy for overcoming some of these difficulties has been development of “lid” getter technology wherein the getter material is formed in a well in a lid that is incorporated after manufacture into an enclosure for the OLED to create an hermetically sealed environment or package for the device. However, these lid getters tend to add undesirable bulk to the finished device.

Thus, there remains a need for a getter that can perform in an organic electronic device over the expected life-time of the device, is adaptable to various modes of application, does not add bulk and extra components, permits flexibility in the design (shape, size, materials) of the organic electronic device, and simplifies the manufacturing of such devices.

### SUMMARY

A method for sealing an electronic device includes providing an electronic device on a substrate, providing a lid, activating a getter material in an environment substantially free of contaminants, applying a sealing material to at least a portion of the lid, and attaching the substrate and the lid in an inert environment. The lid includes a solidified getter material adhered to at least a portion of at least one surface of the lid, wherein the portion of the surface will be an interior surface when the lid is used in the electronic device. The sealing material contacts both the substrate and the lid and the time elapsed between activating the getter material and attaching the substrate and the lid is less than 20 minutes.

A sealing assembly for an electronic device includes an activation tool for activating a getter material, a dispensing tool for dispensing a sealing material, and an encapsulation tool for sealing the electronic device. The sealing assembly is in an environment substantially free of contaminants.

The foregoing general description and the following detailed description are exemplary and explanatory only and are not restrictive of the invention, as defined in the appended claims.

### BRIEF DESCRIPTION OF THE DRAWINGS

Embodiments are illustrated in the accompanying figures to improve understanding of concepts as presented herein.

FIG. 1 includes an illustration of a cross-sectional view of a organic electronic device having a getter in accordance with one embodiment of the present invention.

FIG. 2 includes an illustration of a cross-sectional view of an organic electronic device having an enclosure in accordance with one embodiment of the present invention.

FIG. 3 includes an illustration of a cross-sectional view of an organic electronic device within an enclosure in accordance with one embodiment of the present invention.

FIG. 4 includes an illustration of one pattern of a first getter composition in accordance with one embodiment of the present invention.

FIG. 5 includes an illustration of a second pattern of one getter composition and a second glass frit composition in accordance with one embodiment of the present invention.

FIG. 6 includes an illustration of a pattern of at least two getter compositions and a second glass frit composition in accordance with one embodiment of the present invention.

FIG. 7 includes an illustration of a pattern of getter composition, glass frit composition and adhesive in accordance with one embodiment of the present invention.

FIG. 8 includes an illustration of two patterns of deposited getter compositions in accordance with one embodiment of the present invention.

FIG. 9 includes an illustration of two patterns of deposited getter compositions and a pattern of glass frit composition in accordance with one embodiment of the present invention.

FIG. 10 includes an illustration of a cross-sectional view of an organic electronic device having an edge seal in accordance with one embodiment of the present invention.

Skilled artisans appreciate that objects in the figures are illustrated for simplicity and clarity and have not necessarily been drawn to scale. For example, the dimensions of some of the objects in the figures may be exaggerated relative to other objects to help to improve understanding of embodiments.

### DETAILED DESCRIPTION

In a first aspect, a method for sealing an electronic device includes providing an electronic device on a substrate, providing a lid, activating a getter material in an environment substantially free of contaminants, applying a sealing material to at least a portion of the lid, and attaching the substrate and the lid in an inert environment. The lid includes a solidified getter material adhered to at least a portion of at least one surface of the lid, wherein the portion of the surface will be an interior surface when the lid is used in the electronic device. The sealing material contacts both the substrate and the lid and the time elapsed between activating the getter material and attaching the substrate and the lid is less than 20 minutes.

In one embodiment of the first aspect, the time elapsed is less than 10 minutes. In a more specific embodiment, the time elapsed is in the range of 2 to 5 minutes.

In another embodiment of the first aspect, activating includes heating the getter material to a temperature of at least 300° C. In a more specific embodiment, activating includes heating the getter material to a temperature in a range of 350 to 450° C.

In yet another embodiment of the first aspect, the sealing material includes a spacer material. In a more specific embodiment, the sealing material further includes an epoxy.

In a further embodiment of the first aspect, applying includes nozzle dispensing the sealing material. In still a further embodiment of the first aspect, applying includes screen printing the sealing material.

In still yet another embodiment of the first aspect, the getter material includes a molecular sieve. In a more specific embodiment, the molecular sieve includes a zeolite.

In still yet a further embodiment of the first aspect, the method further includes depositing an edge seal layer in contact with both the lid and the substrate. In a more specific embodiment, depositing includes physical vapor deposition, chemical vapor deposition, sputtering, electron beam deposition, ion beam deposition, atomic layer deposition, and combinations thereof. In a still more specific embodiment, depositing includes atomic layer deposition.

In a second aspect, a sealing assembly for an electronic device includes an activation tool for activating a getter material, a dispensing tool for dispensing a sealing material, and an encapsulation tool for sealing the electronic device. The sealing assembly is in an environment substantially free of contaminants.

In one embodiment of the second aspect, the activation tool includes heating plates. In a specific embodiment, the heating plates include inductive heating coils.

In another embodiment of the second aspect, the encapsulation tool includes a vacuum chamber.

In still another embodiments of the second aspect, the encapsulation tool comprises an ultraviolet light source.

Many aspects and embodiments have been described above and are merely exemplary and not limiting. After reading this specification, skilled artisans appreciate that other aspects and embodiments are possible without departing from the scope of the invention.

Other features and benefits of any one or more of the embodiments will be apparent from the following detailed description, and from the claims. The detailed description first addresses Definitions and Clarification of Terms followed by The Getter Composition, Applying the Getter Composition to the Surface, Heat Treatment of the Getter, Encapsulation, Other Embodiments, Advantages, and finally Examples.

### 1. Definitions and Clarification of Terms

Before addressing details of embodiments described below, some terms are defined or clarified. As used herein, the term “adsorbent” and “adsorbing” refer to a solid material that has the ability to cause molecules of gases or vapors to condense on its surface and be gettered without changing the adsorbent physically or chemically.

As used herein, the term “clay” is intended to mean a mineral particle composition having a diameter less than 1/256 mm (4 microns) and composed of a loosely defined group of hydrous silicate minerals, essentially of aluminum.

As used herein, the term “continuous ledge” is intended to refer to a structure that forms a physical barrier in a continuous pattern. A continuous ledge may form a pattern around the perimeter of a device such that there are no breaks in the pattern, however, the material used for the continuous ledge structure may include discontinuities, such as the openings found in a glass frit material or a molecular sieve material.

As used herein, the term “densifying” or “densification”, as used with respect to the getter composition containing the getter, inorganic binder and liquid medium, is intended to mean heating or reheating the getter composition, driving off substantially all volatiles, including, but not limited to the liquid medium used in the getter composition and moisture of the getter, thus “activating” the getter. The densified getter, when exposed to environmental conditions (including the environment of a sealed electronic device), will adsorb contaminant gases and can be “reactivated” by reheating the getter to drive of contaminant gases.

Densifying is further intended to mean heating the getter materials sufficiently to cause self-adherence of the getter material, particularly the inorganic binder therein, to the surface to which it has been applied. Densifying, may be accomplished in one continuous act, during which process conditions may be adjusted to accomplish the densification of the getter, i.e., bringing the getter composition from the fluid or paste state to a dried or more solid state, and then further heating the solid getter material on the surface to the densified state. Alternatively, when heat treatment is separated into two or more acts, densifying means the heat treatment that brings a “solidified” getter from the “solidified” state, as described herein, to the densified state and in condition to adsorb containment gases.

As used herein, the term “edge seal layer” is intended to mean a layer that covers at least the edge of a first layer and forms a seal between the first layer and a second layer. In one embodiment, an edge seal layer is used in combination with a sealing material to provide a hermetically sealed device.

As used herein, the term “organic electronic device” is intended to mean a device including one or more organic semiconductor layers or materials. An organic electronic device includes, but is not limited to: (1) a device that converts electrical energy into radiation (e.g., a light-emitting diode, light emitting diode display, diode laser, or lighting panel), (2) a device that detects a signal using an electronic process (e.g., a photodetector, a photoconductive cell, a photoresistor, a photoswitch, a phototransistor, a phototube, an infrared (“IR”) detector, or a biosensors), (3) a device that converts radiation into electrical energy (e.g., a photovoltaic device or solar cell), (4) a device that includes one or more electronic components that include one or more organic semiconductor layers (e.g., a transistor or diode), or any combination of devices in items (1) through (4).

As used herein, the term “gas” is intended to mean a phase of matter that expands indefinitely to fill a containment vessel and is characterized by a low density. The phrase “contaminant gases” as used herein, includes moisture, oxygen, hydrogen, hydrocarbon vapors, and other types of gases that may be in the atmosphere or generated internally in an organic electric device.

As used herein, the term “getter” or “gettering” is intended to mean a substance that adsorbs or the act of adsorbing contaminant gases that cause damage to organic layers in electronic devices. The getter materials may also contain a minor proportion of materials that absorb water. For example, certain clays and glass frits that are useful as the inorganic binder in the getters made according to the present methods will absorb water. In one embodiment, the getter comprises a molecular sieve.

As used herein, the term “hermetically sealed” is intended to mean a substantially complete seal against the escape or entry of air.

As used herein, the term “molecular sieve” is intended to mean a crystalline, porous, molecular structure that selectively adsorbs or rejects molecules based on differences in molecular size or shape. The molecular sieve particles suitable for the present invention include alkaline metal oxides, alkaline earth metal oxides, sulfates, metal halides, and perchlorates and mixtures thereof. In one embodiment, the molecular sieve is a zeolite.

As used herein, the term “sealing material” is intended to mean a material used to attached two layers together to form a sealed enclosure. In one embodiment, the sealing material comprises an epoxy. In another embodiment, the sealing material is an epoxy having a spacer material.

As used herein, the term “solidifying” is intended to mean drying sufficiently to stabilize the deposited getter composition, such as to prevent unacceptable spreading of the composition to undesired locations or damage caused by storing the surfaces containing solidified getter (e.g., by stacking). Solidifying can be accomplished as a separate act or can be included in a continuous act that results in the densifying of the getter composition.

As used herein, the term “spacer material” is intended to mean a material whose primary purpose is to provide a separation between two layers. In one embodiment, the spacer material comprises glass beads.

As used herein, the term “surface” is intended to mean the face of a solid object, a component in an organic electronic device, where the getter performance is needed. In one embodiment the surface to which the getter composition is adhered is an interior face of a lid or sealing apparatus that is assembled with at least one other component to form a housing or enclosure for an organic electronic device, or for a module that includes an organic electronic device. In another embodiment, the surface is substantially planar. In another embodiment, the surface has a concave inner portion. The surface may be of any number of materials and may include metal, ceramic and glass and any variety of sizes and shapes. In one embodiment, the surface to which the getter in adhered is a glass lid or plate smaller than 20×20 mm and substantially planar.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

Also, use of the “a” or “an” are employed to describe elements and components of the invention. This is done merely for convenience and to give a general sense of the invention. This description should be read to include one or at least one and the singular also includes the plural unless it is obvious that it is meant otherwise.

Group numbers corresponding to columns within the Periodic Table of the elements use the “New Notation” convention as seen in the CRC Handbook of Chemistry and Physics, 81^{st} Edition (2000-2001).

Unless otherwise defined, all technical and scientific terms used herein have the same meaning as commonly understood by one of ordinary skill in the art to which this invention belongs. Although methods and materials similar or equivalent to those described herein can be used in the practice or testing of embodiments of the present invention, suitable methods and materials are described below. All publications, patent applications, patents, and other references mentioned herein are incorporated by reference in their entirety, unless a particular passage is cited. In case of conflict, the present specification, including definitions, will control. In addition, the materials, methods, and examples are illustrative only and not intended to be limiting.

To the extent not described herein, many details regarding specific materials, processing acts, and circuits are conventional and may be found in textbooks and other sources within the organic light-emitting diode display, photodetector, photovoltaic, and semiconductive member arts.

### 2. The Getter Composition

It has been discovered that when applied to the surface as a getter composition and then solidified thereon, a getter can be densified (colloquially, activated or “fired in place”) at any time prior to sealing the electronic device of interest. A mode of applying the getter composition to the surface can be used wherein its consistency can range from as thick as a paste to as fluid as ink. Moreover, getter structures can be created on the surface in any desired shape or thickness by applying one or more additional separate or overlapping applications of the one or more getter compositions.

The getter composition of the present invention comprises particles of a getter and an inorganic binder, and a liquid medium. The getter composition is applied directly to the surface and densified thereon. The great flexibility in choice of consistency for the getter composition allows application of the getter materials to the surface by a variety of known techniques, with more fluid mixtures providing a thinner layer of getter and paste-like getter compositions providing a thicker getter layer.

The inorganic binder permits a low densification temperature of about 400° C. to about 650° C. and good adhesion between the heat-treated getter and surface. Firing temperature is limited by the choice of surface material (e.g., glass, metal, ceramic) because the getter is densified on the surface to which it is applied, causing self-adherence to the surface. For example, the firing temperature needs to be below 650° C. if a typical glass surface based on soda lime silicates is selected. Firing above 650° C. with the getter on a glass surface may induce warping or distortion of the glass surface. In the case of a surface with a higher melting temperature, such as a metal-based surface, a temperature above 650° C. may be used for densification of the getter.

Thus, adhesion between the getter and surface is improved by selection of a low softening inorganic binder, such as clay particles and/or glass frit. A low softening inorganic binder, such as glass frit and clay binder can help relieve interfacial stress by penetration into voids in the substrate via viscous flow during firing. Mechanical locking is likely to be the dominant mechanism for adhesion between getter and substrate.

The process conditions employed and getter structures formed are compatible with incorporation of the surface into an enclosure for hermetically sealing an OLED, protecting the organic layers therein from moisture and other contaminant gases released from materials within the device as well as from those in the environment.

The electronic devices created using the method of the present invention can have contaminant gases within a sealed enclosure maintained to levels below about 1000 ppm in one embodiment. In another embodiment, the contaminant gases within the enclosed environment of the electronic device is less than about 100 ppm.

The getter composition used in the present methods is a getter composition comprising particles of a getter and an inorganic binder in a liquid medium. The getter can be a molecular sieve, which acts as an adsorbent. The inorganic binder, when fired, adheres the molecular sieve to the substrate. The size of the particles of getter and inorganic binder will vary depending upon the consistency and type of getter composition desired and is selected to be suitable for the mode of application and the nature of the surface to which it is applied. In one embodiment, the getter is a molecular sieve. The particle size of the molecular sieve and inorganic binder can be from about 0.1 to 200 microns. In one embodiment, the particle size of a substantial number of the particles is less than about 20 microns. In one embodiment the particle size of a substantial number of the particles is less than about 10 microns. In one embodiment, a substantial portion of the particles have a size from about 0.1 to 10 microns. In another embodiment, a substantial portion of the particles have a size in the range of from about 2 to 6 microns. In another embodiment, the particles have a size of from about 3 to 5 microns.

In one embodiment, a liquid dispersion having the consistency of a paste is particularly suitable for applying the getter composition by screen-printing, and for this embodiment, the particles can be powder-sized provided that the particles are not so fine that an overly thick paste is created and can not be transferred to the selected portion of the surface that is to receive the getter composition.

In one embodiment, the molecular sieve is a zeolite, either naturally occurring or synthetic. Well known zeolites include chabazite (also referred to as zeolite D), clinoptilolite, erionite, faujasite (also referred to as zeolite X and zeolite Y), ferrierite, mordenite, zeolite A, and zeolite P. Detailed descriptions of the above-identified zeolites, as well as others, may be found in D. W. Breck, Zeolite Molecular Sieves, John Wiley and Sons, Present York, 1974, hereby incorporated by reference. For example, type 3A, 4A and 13X zeolites all have the ability to adsorb water molecules and are often preferred as the adsorbent molecular sieve for making moisture getters. Such zeolites comprise Na₂O, Al₂O₃ and SiO₂.

Certain adsorbent getters can adsorb gaseous contaminants in addition to moisture, such as gaseous H₂ and O₂. An example of a commercially available, solid getter tablet based on zeolite technology that can be made to adsorb contaminant gases, as well as moisture is described in European Patent Application No. WO 02/430098 A1 by Synetix.

Non-limiting examples of clays that are suitable as the inorganic binder in an aqueous dispersion for making a layer of getter material adhered to a surface include attapulgite, kaolin, sepiolite, palygorskite, kaolinite, plastic ball clays, clays of the attapulgite or kaolin types, bentonite, montmorillonite, illite, chlorite, bentonite-type clay, some of which also absorb moisture, and mixtures thereof. Magnesium aluminosilicate clays are often preferred.

In one embodiment, a moisture getter can be formed from particles of a wafer that is commercially available under the trade name TRI-SORB® (Sud-Chemie, Belen, N. Mex.). TRI-SORB® is available as a compressed tablet comprising pre-calcined particles of an A4 zeolite in a binder matrix of magnesium aluminosilicate clay. The A4 zeolite in TRI-SORB® consists of aluminum and silicon oxides in approximately equal amounts with sodium as the counter ion. The tablets are ground to form finely divided particles comprising a zeolite in a matrix of clay.

Additional examples of inorganic binders that can be used in the present methods are glass frits. Non-limiting examples of glass frits that are suitable for inclusion in the inorganic binder in the present methods include those that comprise at least one of PbO, Al₂O₃, SiO₂, B₂O₃, ZnO, Bi₂O₃, Na₂O, Li₂O, P₂O₅, NaF and CdO, and MO where O is oxygen and M is selected from Ba, Sr, PB, Ca, Zn, Cu, Mg, and mixtures thereof. For example, the inorganic binder can be a glass frit comprising 10-90 wt % PbO, 0-20 wt % Al₂O₃, 0-40 wt % SiO₂, 0-15 wt % B₂O₃, 0-15 wt % ZnO, 0-85 wt % Bi₂O₃, 0-10 wt % Na₂O, 0-5 wt % Li₂O, 0-45 wt %, P₂O₅, 0-20 wt % NaF, and 0-10 wt % CdO. In another example, the inorganic binder can be a glass frit comprising: 0-15 wt % PbO, 0-5 wt % Al₂O₃, 0-20 wt % SiO₂, 0-15 wt % B₂O₃, 0-15 wt % ZnO, 65-85 wt % Bi₂O₃, 0-10 wt % Na₂O, 0-5 wt % Li₂O, 0-29 wt % P₂O₅, 0-20 wt % NaF, and 0-10 wt % CdO. Glass frit can be ground to provide powder sized particles (e.g., 2-6 microns) in a ball mill.

A wide variety of liquids can be used in the liquid medium provided that it acts as a carrier or vehicle for the molecular sieve and inorganic binder particles. The liquid medium can comprise water, organic solvents, low molecular weight polymers, and mixtures thereof. Examples of useful solvents include, but are not limited to, ethyl acetate and terpenes such as alpha- or beta-terpineol, kerosene, toluene, dibutylphthalate, butyl carbitol, butyl carbitol acetate, hexylene glycol, and other ethers, glycols, acetates, ether alcohols, esters, keytones, aromatic hydrocarbons, alcohols, alcohol esters, pyrrolidones, and mixtures thereof.

The liquid medium can contain additives suitable for conferring desired rheological and viscosity properties to the getter composition. A polymer and resins can be added to the liquid medium to aid in formation of a stable dispersion of the particles. For example, methyl cellulose, ethylhydroxyethyl cellulose, wood rosin, or mixtures of ethyl cellulose can be dissolved in a phenolic resin, a polymethacrylate of lower alcohols, or monobutyl ether of ethylene glycol monoacetate, and mixtures thereof. Surfactants and other processing aids may also be added to the liquid medium.

The type and amount of liquid medium used is selected to be substantially completely volatilized upon heat treatment (i.e., during solidification and densification) of the getter composition (or as in one embodiment, when a second composition consisting essentially of glass frit inorganic binder particles is applied to the surface in addition to at least one getter composition), adhering the respective particles to the surface. The amount of the liquid medium is no greater than that which gives the type of getter composition desired and is such that the getter composition does not pour or flow easily, but rather needs some additional force or energy to be spread or to be applied to a surface. In one embodiment the getter composition has a liquid consistency in the range from a thick paste to a fluid ink. In another embodiment, the amount of the liquid medium is just sufficient to achieve a dispersion of the particles of inorganic binder and molecular sieve used, and will vary depending upon their choice. In one embodiment, the liquid medium is about 10 wt. % of the getter composition. In one embodiment, the liquid composition is less than about 30 wt. % of the getter composition. In another embodiment, the liquid medium is less than about 50 wt. % of the getter composition.

In one embodiment of the getter composition, the weight ratio of molecular sieve to inorganic binder material is at least about 1:1. In another embodiment, the weight ratio of molecular sieve to inorganic binder material is at least about 3:1. In another embodiment, the weight ratio of molecular sieve to inorganic binder material is at least about 6:1. The upper limit on the weight ratio of molecular sieve to inorganic binder is determined only by the amount of inorganic binder necessary to achieve good adhesion of the molecular sieve to the substrate.

Certain clays and glass frits are inherently water absorbing, as is known in the art. Therefore, when such binders are used in the getter compositions, the amount of molecular sieve to be added to the getter composition may be slightly less than would otherwise be needed to provide adequate capacity to adsorb the moisture and contaminant gas in any given situation (e.g., when the getter is incorporated into the enclosure and the enclosure is sealed shut). The water uptake or gas uptake capacity of the molecular sieve is a known property and is substantially unimpaired by the inorganic binder, which does not encase the molecular sieve particles completely, but allows the pores to remain substantially open. The volume of the interior of the device and the amount of water and/or gas in the air in the enclosure can be readily determined. Taking these factors into account an adequate weight of getter materials can be determined and incorporated into the getter composition.

The proportion of liquid medium in the getter composition controls the thickness of the getter composition applied as well as the mode of application. A dispersion having the consistency of a thick paste results in formation of a thicker getter layer (such dispersions are subject to shear-thinning and hence becomes thinner as the dispersion is worked on the surface). A watery composition, on the other hand, results in formation of a thinner film of solid getter when solidified.

In one embodiment, the getter composition comprises at least particles of synthetic zeolite, natural zeolite and clay in an aqueous medium. In another embodiment, the getter composition comprising particles of natural or synthetic zeolite and powdered glass frit in an organic liquid medium, as disclosed herein, but is substantially water-free.

### 3. Applying the Getter Composition to the Surface

The consistency of the dispersion of the getter composition is conveniently selected to accommodate the method of applying it to a surface and the area and thickness of getter material desired for its final use. The solid particles in the getter composition are preferably mixed with the liquid medium by mechanical mixing to form a composition, having suitable consistency and rheology, for application using any technique for applying a getter composition to a solid surface, including those well known in the art, such as by printing, such as silk screen printing or ink-jet printing, or coating by spraying, brushing, extruding, dispensing, syringe dispensing, stenciling, hand probe, doctor blading, and spin-coating. In one embodiment, the goal in selecting the proportions of the liquid medium and particles of getter and inorganic binder in the getter composition is to barely use enough of the liquid to form the desired type of getter composition and/or thickness of the resulting getter layer. For example, printing techniques may be used to achieve a getter composition thickness of no more than about 10 microns. The getter composition used in the present method can also be applied to a surface in such a manner as to create a layer of getter having a shape or outline, pattern, and thickness, which will depend on design of the organic electronic device to be protected. Once applied to the surface, the getter composition is heat treated in a one- or multiple-step process involving solidification of the liquid to form a solid layer and densification of the solid layer by heating to obtain the solid layer adhered to the surface and to activate the getter.

In one embodiment, when the organic electronic device is an OLED, and the surface is the interior surface of the OLED lid, the getter composition is spread or otherwise coated onto the surface of the lid, usually a planar surface. One or more additional layers of the same or different getter composition can also be applied and/or a single layer can be applied in a pattern. In one embodiment, the OLED is a passive matrix device built on a glass substrate and the thickness of the getter composition used is no thicker than in the sub-micron range, in another embodiment the getter composition is thicker, for example in the tens of microns range. In other OLED devices, the thickness may vary depending on the size and the materials from which the OLED device is made.

In one embodiment, the getter composition is applied to maximize the surface area. This can be accomplished by applying the getter composition to substantially the entire surface available.

One embodiment of an electronic device with a getter prepared according to the methods described herein is illustrated in FIG. 1. Lid 4, which has a layer of getter 10 is adhered by means of a bead of epoxy 12 to substrate 6, which has active layers 8. In an OLED the active layers comprise an anode, a cathode and a light-emitting layer positioned therebetween. In one embodiment, the epoxy 12 can include spacers that hold the getter 10 and lid 4 spaced apart from the active layers 8 of the organic electronic device. In one embodiment, the spacers can comprise glass beads of a single size selected to provide the desired space between the active layers 8 and both the getter 10 and lid 4. In one embodiment, the diameter of the glass beads can be at least about 30 microns. In another embodiment, the diameter of the glass beads can be at least about 40 microns. In a specific embodiment, the epoxy 12 can include 50 micron glass beads in a range of approximately 1 to 5% by volume. In a more specific embodiment, the epoxy 12 can include 50 micron glass beads in a range of approximately 1.5 to 2.5% by volume. The density of spacers in the epoxy can be selected such that they reliably provide a uniform spacing around the entire device. For instance, a density of spacers that is too low may result in contact of the getter 10 or lid 4 with the active layers 8. Alternatively, a density of spacers that is too high may result in stacking of spacers and a larger gap between the substrate 6 and the lid 4. A larger gap between the substrate 6 and lid 4 not only results in a thicker device, but may also form a poorer seal, allowing more contaminants to diffuse into the device. Skilled artisans will appreciate that the size of the spacers and the amount used can be varied to suit a particular application.

In one embodiment, one or more additional layers of the same or a different getter composition, can be applied to the surface, either before or after densification of the first layer. For example, a second layer of the same getter composition can be applied to overlap at least a part of the first layer. In one embodiment, as illustrated in FIG. 2, a planar lid 4 has a first getter layer 10 and a second getter layer 14. The second layer of the getter composition 14 can be applied over the periphery of the first getter layer 10 to build up a spacer ledge that holds the first getter layer 10 and the device lid 4 spaced apart from the active layers 8 of the organic electronic device. A bead of epoxy 12 can be placed around the exterior of the ledge (as illustrated) or the on the surface just inside of the ledge to seal the lid to the substrate of the device. This embodiment provides the additional advantage that the ledge of getter material blocks transmission of contaminant gases through the bead of epoxy into the sealed device. If the epoxy bead is placed exterior to the ledge, the getter ledge also blocks transmission of outgases from the epoxy bead into the device.

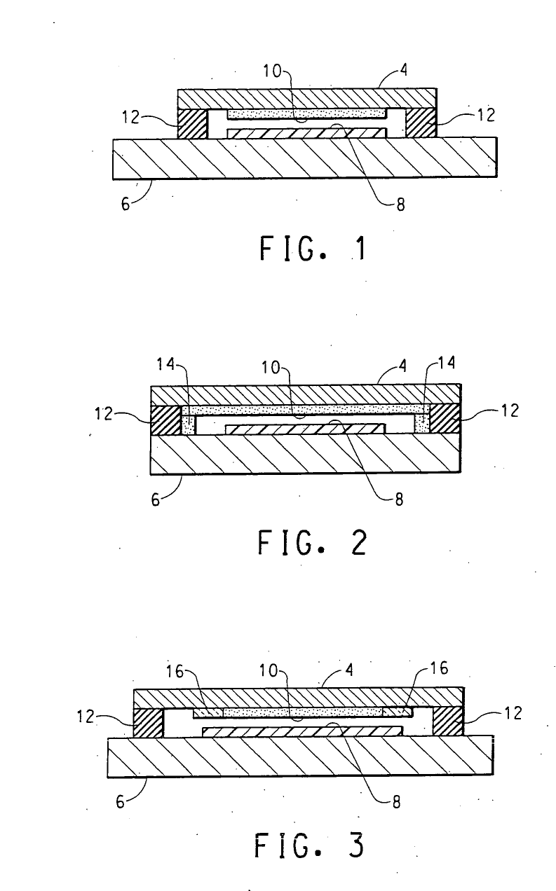

In another embodiment, illustrated in FIG. 3, a planar lid 4 has a first getter layer 10 and a glassy frame 16, and is positioned over the active layers 8 on substrate 6. In this embodiment, one or more optional layers of a second composition is applied to the surface that is exterior to the periphery of the getter layer (rather than overlapping on the getter layer). In this embodiment, the second getter composition can comprise particles of glass frit (e.g., glass frit powder) in organic liquid medium, as disclosed herein, but does not contain molecular sieve. When densified, the layer(s) of the second getter composition form a glassy frame around the getter layer, containing the getter material in place during the densification procedure. This “frame” is particularly useful when the getter composition has properties that allow the components to become “runny” during densification, since the glass frit will become molten enough to adhere to the surface at a lower temperature than is required to densify the getter layer.

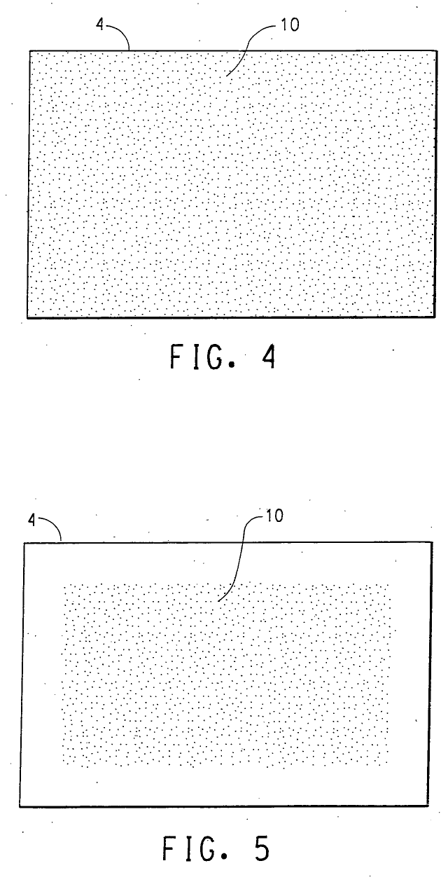

Some non-limiting examples of different patterns of getter composition and glass frit composition on lid 6 are illustrated in FIGS. 4-9. In FIG. 4 there is a uniform layer 10 of getter composition. Densification, discussed below, can be accomplished separately from the drying/solidification step.

In one embodiment, illustrated in FIG. 5, there is a uniform layer of getter composition 10 and a patterned layer of glass frit composition 16.

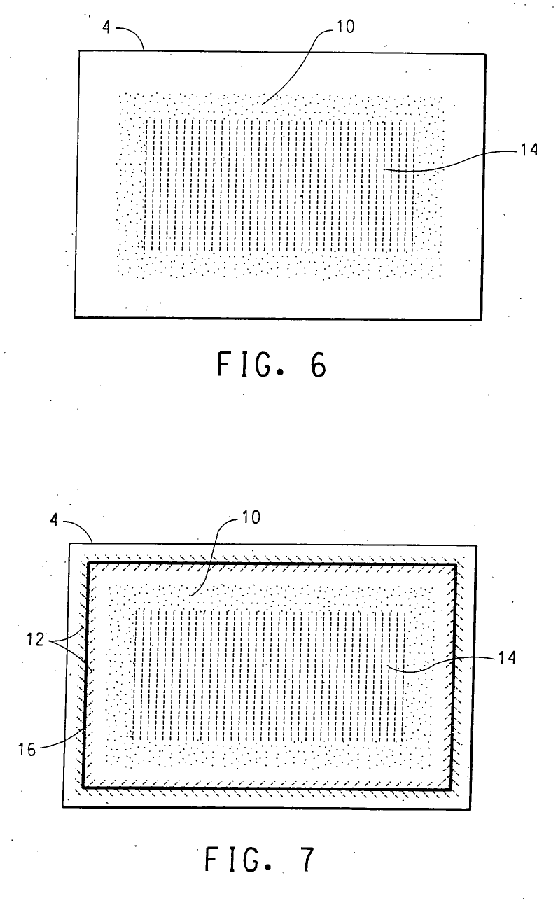

In another embodiment, illustrated in FIG. 6, there is a first patterned layer of getter composition 10, and a second patterned layer of getter composition 14. The second patterned layer partially overlaps the first pattern, and may be of the same or different composition. In one embodiment (not illustrated) there are more than two patterns of getter composition, which can, but need not, overlap.

In yet another embodiment, illustrated in FIG. 7, there is a first patterned layer of getter composition 10 and a spaced apart patterned layer of glass frit composition 16. Optional adhesive layer 12 can be applied after densification as one means to secure the lid to the electronic device.

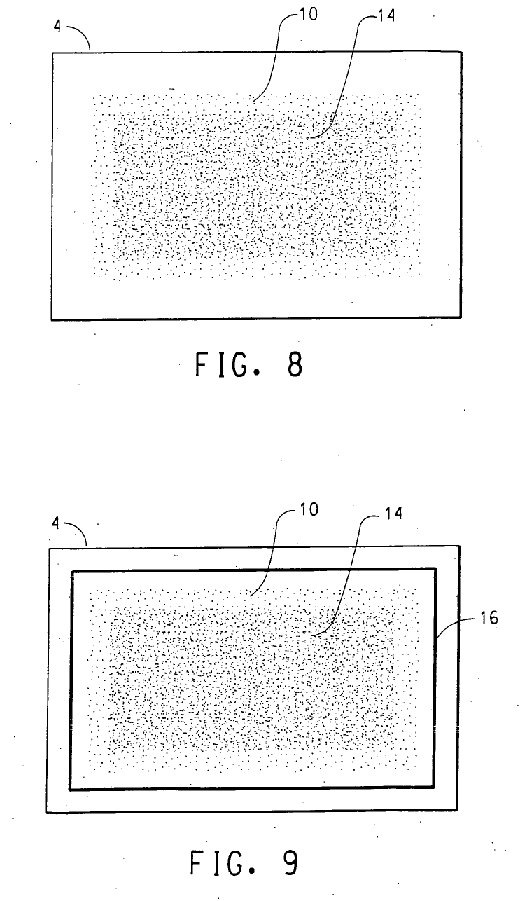

In a further embodiment, illustrated in FIG. 8, there is a first patterned layer of getter composition 10, and a spaced-apart second patterned layer of getter composition 14. The getter compositions can be the same or different.

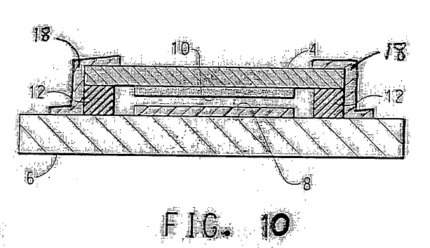

In still a further embodiment, illustrated in FIG. 9, there is a first overall layer of getter composition 10, a second patterned layer of getter composition 14, and a patterned layer of glass frit composition 16. The getter compositions can be the same or different.

### 4. Heat Treatment of the Getter

The getter composition (and any optional layers of getter composition) is heat treated directly on the surface to dry the composition, adhere the getter to the surface, and activate the getter. Heat treatment may take place in one continuous step (varying process conditions as needed during the continuous process) or in two or more steps, as manufacturing convenience dictates.

The heat-treatment step(s) are similar whether the getter composition comprises water or organic medium as the liquid, although the exact times and temperatures selected may vary. In the first step (or portion of the continuous process), the getter composition is solidified, at least sufficiently to prevent running or deformation of the getter layer. For example, the coated surface can be dried at room temperature or heated to remove the low-boiling materials by heating to a temperature of less than about 100° C. The solidifying step may require from about 1 hour to about 3 hours at this temperature. There is no need to control the moisture or gas environment during the solidifying step of the heat treatment. The surface bearing a solidified layer of getter can be conveniently stored at atmospheric conditions until its use is desired. For example, a lid for a device enclosure bearing a solidified coating of getter can be prepared independently of the manufacture of the organic electronic device and stored until such time as it is needed. Then the lid can be heat-treated to densify and activate the getter immediately prior to enclosing the device to form a hermetically sealed atmosphere.

Thus, the densifying step can optionally be a separate second step in heat treatment of the getter. In densification, the inorganic binder becomes molten to promote adherence of the getter to the surface, while any remaining volatiles are driven off (i.e., water or organic liquid medium). For densification, the getter materials can be heated to a temperature of at least about 400° C., such as about 450° C. to about 550° C. or about 650° C. To prevent readsorption of volatiles (and de-activation of the getter), the densifying step can be conducted in a controlled atmosphere void of moisture and other gases, such as under vacuum. In this case, the densifying step is usually performed immediately prior to sealing the device into the hermetic enclosure unless the densified getter is stored in an atmosphere void of moisture and/or other gases. Alternatively, solidification and densification can be performed as a single continuous process or step by slowly raising the temperature to the densifying temperature. In this alternative embodiment of heat treating, the getter materials must be held at densifying conditions as described above (e.g. in an environment void of contaminant gases) for a period of time sufficient to ensure that the binder flows into voids in the substrate to provide adhesion, and all volatiles have been driven from the getter to provide full gettering capability for the getter. In still another embodiment, densification (whether in one ore more steps) under atmospheric conditions can be performed, and then the getter can be activated separately by reheating at any time (usually requiring a temperature of about 200° C.) in a moisture- and contaminant gas-free environment, such as under nitrogen gas, just prior to assembly of the device into an enclosure.

In one embodiment, the activation can be performed in a moisture- and contaminant gas-free environment, such as under nitrogen gas, just prior to assembly of the device into an enclosure. The heating tool used for activation can be a part of the encapsulation assembly, thus minimizing the time between activation and encapsulation. In one embodiment, an in-line heating tool can include inductive heating coils embedded in metal heating plates to provide rapid heating to temperatures of at least about 300° C., such as about 350° C. to about 450° C. or about 550° C. At lower activation temperatures a longer heating time is required to fully active the getter, while at higher temperatures, full activation of the getter will require less time, although the time required to heat up and cool down will be longer. Skilled artisans will appreciate that the selection of the activation temperature and time can be optimized to best suit the design of the encapsulation process being used. In one embodiment, multiple heating elements can be used for more rapid heating. In one embodiment, a cooling system may be used for more rapid cooling. In one embodiment, the time between completion of activation and sealing of the lid to the device, is less than about 20 minutes. In one embodiment, the time is less than about 10 minutes. In one embodiment the time is in a range of about 2 to 5 minutes.

When densified, the present activated getter is a porous solid, self-adhered to the surface without the need for attachment by other means, such as by adhesive. In one embodiment, particles of molecular sieve contained in the getter provide a controlled pore structure into which water and/or molecules can travel and undergo physical adsorption and be trapped and not released into the environment inside the enclosure.

Thus, by using the present method of adhering a getter material to a solid surface, the getter can be “fired in place” on any surface that can withstand the heat treatment process, such as on the interior surface of a enclosure lid before the enclosure is assembled. The enclosure can then be assembled (in an environment devoid of contaminant gases) to incorporate the surface while encapsulating a moisture- and/or gas-sensitive organic electronic device to create a hermetic environment for the device or for a module comprising two or more such devices.

### 5. Encapsulation

In one embodiment, the lid having the densified and activated getter material thereon is sealed to an electronic device without exposure to air and no exposure, or only minimal exposure, to water environments, such as in a low water environment of a dry box. The getter compositions described herein are sensitive enough to trap moisture even in dry box environments having only ppm levels of water. In one embodiment, the lid having the activated getter material is sealed to the electronic device immediately after activation. In one embodiment, the time between completion of activation and sealing of the lid to the device, is less than about 120 minutes. In one embodiment, the time is less than about 60 minutes.

In one embodiment, the lid having the densified and activated getter material thereon is stored in a chamber capable of maintaining an absolute pressure of 760 to 10⁻⁴ torr, or less. The lid can then be sealed to the electronic device under vacuum. In this embodiment, when the exterior environment rises to ambient pressure after sealing the device, the pressure difference between the interior and exterior of the device helps to hold the substrate and lid together and provide a stronger seal. In a specific embodiment, when sealing the lid to the electronic device under vacuum, a layer of getter composition that forms a ledge can be used to form a barrier to prevent epoxy from contaminating the interior of the device when the exterior environment rises to ambient pressure. In the embodiment illustrated in FIG. 2, for example, the epoxy 12 can be applied on the exterior of the ledge formed by the second getter layer 14. When the device is sealed and the exterior pressure rises, the second getter layer 14 retards the flow of the epoxy 12 being pushed towards the interior of the device by the pressure differential between the interior and exterior of the device. Alternatively, the lid can be sealed to the electronic device in a low water environment within a short time period after removal from full vacuum. In one embodiment, after being removed from full vacuum, the lid is exposed to the low water environment for less than about 120 minutes. In one embodiment, the lid is exposed to the low water environment for less than about 60 minutes.

In one embodiment, the lid having the densified and activated getter material thereon is at an elevated temperature when it is sealed to an electronic device. This can be accomplished by using the lid after densification and before it has completely cooled. Alternatively, the lid can be completely cooled and reheated prior to sealing to the device. In one embodiment, the lid is at a temperature greater than about 50° C. In one embodiment, the lid is at a temperature greater than about 100° C. In most embodiments the temperature will not exceed about 200° C.

In one embodiment, the lid having the densified and activated getter material thereon is sealed to an electronic device without exposure to air and only minimal exposure to low water environments such as dry boxes, and further is at an elevated temperature.

### 6. Other Embodiments

In one embodiment, as illustrated in FIG. 10, an edge seal 18 can be formed to further reduce the migration of contaminants from the ambient environment into the organic electronic device. The edge seal 18 can be formed to cover the perimeter of the lid 4, any exposed epoxy 12, and any part of the substrate 6 or lid 4. Materials that have low electrical conductivity, good heat resistance, low diffusion of moisture or other contaminants, and that provide good adhesion to the lid 4, epoxy 12 and substrate 6 materials can be selected for the edge seal 18. Example of edge seal materials include inorganic metal oxides (e.g., silicon oxides, aluminum oxides, etc.), inorganic metal nitrides (e.g., silicon nitrides, aluminum nitrides, etc.), and mixtures thereof (e.g., silicon oxynitrides, aluminium oxynitrides, etc.). The edge seal 18 can be deposited using a variety of techniques, including thermal physical vapor deposition, chemical vapor deposition, plasma-enhanced chemical vapor deposition, laser-induced chemical vapor deposition, sputter deposition, electron beam deposition, ion beam sputter deposition, and atomic layer deposition. The edge seal 18 can have a thickness in the range of about 1 to 10,000 Angstroms. In one embodiment, atomic layer deposition is used to deposit an edge seal 18 of aluminum oxide 500 Angstroms thick.

For convenience, the present method of preparing a packaged electronic device comprising a layer of getter adhered to the interior surface of a hermetically sealed enclosure is illustrated with reference to an OLED. However the invention is conceived to encompass any type of moisture- and/or gas-sensitive device, including without limitation, any type of organic electronic device. It is also contemplated within the scope of the invention that a module packaged according to the present methods may combine two or more such devices within a single hermetically sealed enclosure.

### 7. Advantages

The present methods for adhering a getter to a substrate are completely independent of the manufacturing of the device. Since heat treatment of the getter is independent of the device, no special consideration of the sensitivities of the device need be taken in manufacturing of the getter and no special consideration of the sensitivities of the getter (i.e., deactivation) need be taken in manufacturing of the device until the getter is encapsulated along with the device into the enclosure.

The use of spacers in the epoxy allows for the use of thin flat glass for both the substrate and the lid, greatly reducing the thickness of the device when compared to a cavity-type lid. In addition, this embodiment simplifies the encapsulation process, reducing process time and costs, and even reducing the amount of time needed to design encapsulations schemes for new or different devices.

In-line activation of the getter minimizes the exposure of the activated getter to the ambient environment, and thus maximizes its effectiveness in trapping harmful contaminants within the device.

The remarkable improvement in stability and lifetime of the gas-sensitive organic electronic device, when hermetically sealed in an enclosure along with the present solid getter, as described herein, is illustrated in the Examples. In particular, encapsulation with an absorbing zeolite material as desiccant significantly outperforms barium-oxide as desiccant, which removes moisture by chemical absorption.

### EXAMPLES

The concepts described herein will be further described in the following examples, which do not limit the scope of the invention described in the claims.

### Example 1

This example illustrates the present invention applying the getter composition. The getter composition was a liquid dispersion of particles of a zeolite-based molecular sieve and glass frit in an organic liquid medium. The dispersion comprised the following ingredients by wt % of total dispersion:

Inorganic Components:

| | |
|---|---|
| Zeolite-based molecular sieve (13x-typed powder) | 54.1 |
| Glass frit | 5.4 |

Organic Components:

| | |
|---|---|
| surfactant | 1.1 |
| ethylcellulose resin | 1.0 |
| Texanol solvent (ester alcohol) | 38.4% |

The composition of the glass frit in wt % (dry) was as follows:

| SiO₂ | Al₂O₃ | B₂O₃ | CaO | ZnO | Bi₂O₃ |
|---|---|---|---|---|---|
| 7.11 | 2.13 | 8.38 | 0.53 | 12.03 | 69.82 |

### Example 2

This example illustrates making and performance of method of applying the getter composition of the present invention. A slurry of 0.75 tablets of unfired DESIWAFER 300/20 zeolite-clay material in 1 ml of water was dispersed in water to make a 200 ml dispersion. The dispersion was applied to a cavity on a glass lid plate in 0.5 ml aliquots by hand using a syringe. The getter was solidified by placing in a vacuum oven for 1 hour at 70° C. to remove substantially all of the water. After solidification, the getter layers were then activated and densified by heating the glass lid plates for 2 hours at 500° C. In an environment having less than 10 ppm H₂O and O₂, the plates with self-attached getter layers were then each assembled into an enclosure holding a polymer light emitting diode device (“PLED”). Control devices were assembled into an enclosure under the same conditions, except that the getter layer was replaced by a fired DESIWAFER tablet (Sud-Chemie) attached to a plate by dispensing an adhesive, placing the tablet on the adhesive and UV curing the adhesive to secure the tablet to the lid cavity. All encapsulated PLEDs, including controls, were then placed in a storage test environment of 70° C. and 95% RH overnight and tested for moisture degradation by measuring pixel shrinkage. The pixel shrinkage for the devices protected by the getter layer made by the present methods was 8-10% vs. 5-7% for the controls using the fired DESIWAFER tablets.

### Example 3

This example illustrates the use of a sealing composition comprising spacer beads dispersed in epoxy to provide the separation between two flat plates in an organic electronic device. This example further illustrates the use of a getter ledge for sealing under reduced pressure.

An approximately 30 micron getter layer was formed on an approximately 0.3 mm thickness flat glass lid using the method as described in Example 2. The getter layer was formed in a pattern to provide a ledge around the perimeter of a device. An OLED was formed on an approximately 0.3 mm thickness flat glass substrate, and an epoxy containing 2% by volume of 50 micron glass frit beads was used to seal the lid to the OLED. The epoxy was applied to the exterior of the getter ledge and the device was sealed under vacuum. The resulting device had a thickness of approximately 0.64 mm.

### Example 4

This example illustrates the use of an in-line activation tool as part of the encapsulation assembly.

Inductive heating coils are embedded in metal heating plates as part of an encapsulation assembly. The entire encapsulation assembly is contained in a moisture- and contaminant gas-free environment under nitrogen gas. Glass plates containing lids with solidified getter are stored in the same nitrogen gas environment. For activation of the getter, an individual glass plate is placed on the heating tool containing the heating plates, which are then heated to 380° C. in about 2-3 minutes, held at 380° C. for about 4-5 minutes, and then cooled to ambient temperature in about 2-3 minutes. The glass plate then moves to a dispensing tool, where an epoxy sealing material is applied, and on to the encapsulation tool where the lids are attached to OLED devices under vacuum. The total time between activation of the getter and encapsulation of the devices is about 2-5 minutes.

Note that not all of the activities described above in the general description or the examples are required, that a portion of a specific activity may not be required, and that one or more further activities may be performed in addition to those described. Still further, the order in which activities are listed are not necessarily the order in which they are performed.

In the foregoing specification, the concepts have been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

It is to be appreciated that certain features are, for clarity, described herein in the context of separate embodiments, may also be provided in combination in a single embodiment. Conversely, various features that are, for brevity, described in the context of a single embodiment, may also be provided separately or in any subcombination. Further, reference to values stated in ranges include each and every value within that range.

What is claimed is:

1. A method for sealing an electronic device, the method comprising:
providing an electronic device on a substrate,
providing a lid, wherein the lid comprises a solidified getter material adhered to at least a portion of at least one surface of the lid, wherein such portion of the surface will be an interior surface when the lid is used in the electronic device;
activating the getter material in an environment substantially free of contaminants;
applying a sealing material to at least a portion of the lid; and
attaching the substrate and the lid in an inert environment,
wherein the sealing material contacts both the substrate and the lid and the time elapsed between activating the getter material and attaching the substrate and the lid is less than 20 minutes.

2. The method of claim 1, wherein the time elapsed is less than 10 minutes.

3. The method of claim 2, wherein the time elapsed is in the range of 2 to 5 minutes.

4. The method of claim 1, wherein activating comprises heating the getter material to a temperature of at least 300° C.

5. The method of claim 4, wherein activating comprises heating the getter material to a temperature in a range of 350 to 450° C.

6. The method of claim 1, wherein the sealing material comprises a spacer material.

7. The method of claim 6, wherein the sealing material further comprises an epoxy.

8. The method of claim 1, wherein applying comprises nozzle dispensing the sealing material.

9. The method of claim 1, wherein applying comprises screen printing the sealing material.

10. The method of claim 1, wherein the getter material comprises a molecular sieve.

11. The method of claim 10, wherein the molecular sieve comprises a zeolite.

12. The method of claim 1, further comprising depositing an edge seal layer in contact with both the lid and the substrate.

13. The method of claim 12, wherein depositing comprises physical vapor deposition, chemical vapor deposition, sputtering, electron beam deposition, ion beam deposition, atomic layer deposition, and combinations thereof.

14. The method of claim 13, wherein depositing comprises atomic layer deposition.

15. A sealing assembly for an electronic device comprising:
an activation tool for activating a getter material;
a dispensing tool for dispensing a sealing material; and
an encapsulation tool for sealing the electronic device,
wherein the sealing assembly is in an environment substantially free of contaminants.

16. The sealing assembly of claim 15, wherein the activation tool comprises heating plates.

17. The sealing assembly of claim 16, wherein the heating plates comprise inductive heating coils.

18. The sealing assembly of claim 15, wherein the encapsulation tool comprises a vacuum chamber.

19. The sealing assembly of claim 15, wherein the encapsulation tool comprises an ultraviolet light source.
